(19) United States
(12) Patent Application Publication
(10) Pub. No.: US 2002/0020867 A1
(43) Pub. Date: Feb. 21, 2002

(54) Semiconductor device and method of manufacturing same

(75) Inventors: Katsuomi Shiozawa, Tokyo (JP); Takashi Kuroi, Tokyo (JP); Hiroshi Umeda, Tokyo (JP); Katsuyuki Horita, Tokyo (JP)

Correspondence Address: OBLON, SPIVAK, McCLELLAND, MAIER & NEUSTADT, P.C., FOURTH FLOOR, 1755 JEFFERSON DAVIS HIGHWAY, ARLINGTON, VA, 22202, US

(73) Assignee: MITSUBISHI DENKI KABUSHIKI KAISHA, Tokyo (JP)

(21) Appl. No.: 09/732,766

(22) Filed: Dec. 11, 2000

(30) Foreign Application Priority Data
Jul. 25, 2000 (JP) P2000-223923

(51) Int. Cl. H01L 27/108; H01L 29/76

(52) U.S. Cl. 257/301

(57) ABSTRACT

A trench is formed in a silicon substrate (1) and an oxide film (11) is provided on an inner wall of the trench. The trench is filled with an oxide film (7) through the oxide film (11). A gate oxide film (14) is formed on the silicon substrate (1). A bottom of a recess F2, defined by the gate oxide film (14) and the oxide films (11, 17), is arranged in a position more approximated to the oxide film (7) for filling the trench than a boundary between the silicon substrate (1) and the oxide film (11). A concentration of a field from a gate electrode (16) is suppressed in the vicinity of the element isolation.

### BACKGROUND OF THE INVENTION

1. Field of the Invention

The present invention is directed to a semiconductor device, more particularly to a so-called trench type element isolation in which a trench formed in a silicon substrate is filled with an insulator.

2. Description of the Background Art

FIGS. 13 to 20 are cross-sectional views showing a background art method of manufacturing a semiconductor device, more particularly a trench type element isolation. As shown in FIG. 13, a thermal oxide film 3 and a silicon nitride film 2 patterned by the techniques such as photolithography or dry etching are formed on a silicon substrate 1. The thermal oxide film 3 and the silicon nitride film 2 remain on an active region, a region in which a MOSFET is formed, for example. Moreover, element isolation is formed in a region in which an opening of the thermal oxide film 3 and the silicon nitride film 2 is defined to expose the silicon substrate 1.

The silicon substrate 1 is selectively etched using the patterned thermal oxide film 3 and the silicon nitride film 2 to form a trench 4 (FIG. 14). Thereafter, thermal oxidation is performed to form a thermal oxide film 5 on an inner wall of the trench 4 (FIG. 15). FIG. 16 is a cross-sectional view showing E1 in an enlarged manner which is a part of the structure of FIG. 15. A rounded portion 6 is formed in the opening of the trench 4 at a boundary between the thermal oxide films 3, 5 and the silicon substrate 1. The rounded portion 6 gives a convex shape to the silicon substrate 1 and a concave shape to the thermal oxide films 3 and 5.

Thereafter, the trench 4 is filled with an oxide film 7 consisting of TEOS (tetraethylorthosilicate) or formed by HDP-CVD (high-density plasma chemical vapor deposition) method (FIG. 17). The oxide film 7 is planarized using the silicon nitride film 2 as a stopper by the known planarization methods such as etching or chemical-mechanical polishing (FIG. 18). The silicon nitride film 2 and the thermal oxide film 3 are removed to obtain trench type element isolation B (FIG. 19). Thereafter, a gate oxide film 10 is formed (FIG. 20) and a transistor (not shown) having a channel width in a direction horizontal to the plane of the drawing is formed.

However, due to concentration of a gate electric field in the vicinity of the trench type element isolation B formed in accordance with the above-mentioned method, fluctuation in a threshold value which is a so-called reverse narrow channel effect becomes noticeable. FIG. 21 is a graph schematically showing the reverse narrow channel effect. While the threshold value of the transistor approximates saturation accompanied by the increase in the channel width, the threshold value suddenly decreases accompanied by the decrease in the channel width due to the influence of the gate electric field strengthened at an end of the channel width direction, namely in the vicinity of the opening of the trench type element isolation B.

As the device sizes shrink, influence of dispersion in the device sizes grows and fluctuation in the threshold value becomes noticeable, resulting in the unstable operations of the devices. Consequently, design margins for a transistor decrease by the reverse narrow channel effect.

The rounded portion 6 is formed once in the aforementioned technique which is shown in FIG. 16. As shown in FIG. 22 showing E2 in an enlarged manner which is a part of the structure of FIG. 19, the size of a rounded portion 6a formed at a boundary between the thermal oxide film 5 and the silicon substrate 1 is smaller than the size of the rounded portion 6 due to removal of the oxide film 3. In order to relax concentration of the gate electric field in the vicinity of the trench type element isolation B, however, it is desirable not to arrange an angle between the thermal oxide film 5 and the gate oxide film 10 to be steep.

Such reduction in the size of the rounded portion can be recovered to some extent by forming the gate oxide film 10. FIG. 23 is a cross-sectional view showing E3 in an enlarged manner which is a part of the structure of FIG. 20. A rounded portion 6b is formed at a boundary between the thermal oxide film 5, the gate oxide film 10 and the silicon substrate 1. However, a recess F1 having a convex shape toward the silicon substrate 1, namely giving a concave shape to the thermal oxide film 5 and the gate oxide film 10 as an integral insulating film, is formed in the vicinity of a boundary between the thermal oxide film 5 and the gate oxide film 10. In accordance with the background technique, a bottom of the recess F1 is likely to be arranged more spaced from the oxide film 7 than the boundary between the silicon substrate 1 and the thermal oxide film 5 by a distance δ(>0). Therefore, even when the rounded portion 6b is provided, such structure results in the problem that an electric field from a gate electrode (not shown) formed on this insulating film concentrates in the recess F1. As a result, increase in junction leakage current as well as decrease in the threshold voltage is caused by the recess F1.

### SUMMARY OF THE INVENTION

A first aspect of the present invention is directed to a semiconductor device comprising: a first insulating film formed on an inner wall of a trench formed in a silicon substrate; and a second insulating film formed on a surface of said silicon substrate, wherein a bottom of a concave portion defined by the first insulating film and the second insulating film is arranged in a position more approximated to an inside of the trench than the inner wall of the trench.

According to a second aspect of the present invention, in the semiconductor device according to the first aspect, the silicon substrate has a convex shape with a radius of curvature of 30 mn or more in a vicinity of an opening of the trench.

According to a third aspect of the present invention, in the semiconductor device according to the first or second aspect, the first insulating film has a thickness of 50 nm or less.

A fourth aspect of the present invention is directed to a method of manufacturing a semiconductor device, comprising the steps of (a) obtaining a trench in a silicon substrate and a first silicon oxide film provided on the silicon substrate on a periphery of the opening of the trench; (b) oxidizing the first silicon oxide film exposed to the trench and an inner wall of the trench by performing a first RTO to form a second silicon oxide film; (c) filling an inside of the trench with a third silicon oxide film; (d) exposing a surface of the silicon substrate with etching for silicon oxide; and (e) performing a second RTO to form a fourth silicon oxide film on the surface of the silicon substrate.

According to a fifth aspect of the present invention, in the method of the fourth aspect, the first RTO and the second RTO are performed at a temperature of 1000° C. or more.

According to a sixth aspect of the present invention, in the method of the fifth aspect, a rate of temperature rising in the first RTO and the second RTO is 100° C. per second or more.

According to a seventh aspect of the present invention, in the method of any one of the fourth to sixth aspects, a percentage of a moisture content to a total gas content in the first RTO and the second RTO is from 20 to 40%.

In the semiconductor device according to the first or second aspect of the present invention, when a gate electrode of a transistor isolated by the first insulating film is provided on the first and the second insulating films, concentration of an electric field from the gate electrode can be suppressed.

In the semiconductor device according to the third aspect of the present invention, the trench can be filled with an insulating film through the first insulating film.

In the method according to the fourth aspect of the present invention, it is possible to enlarge a radius of curvature of a convex shape in the silicon substrate 1 in the vicinity of the opening of the trench. Moreover, a bottom of a concave portion defined by the second and the fourth silicon oxide films can be arranged more approximated to the inside of the trench than the inner wall of the trench.

In the method according to the fifth aspect of the present invention, the radius of curvature of a convex shape in the silicon substrate can be enlarged appropriately.

In the method according to the sixth aspect of the present invention, oxidation at a temperature necessitating reduction in size of the radius of curvature of a convex shape in the silicon substrate can be suppressed.

In the method according to the seventh aspect of the present invention, a degree of oxidation rate is suppressed to control a thickness of the second silicon oxide film easily. Moreover, an effectiveness of rounding the convex shape of the silicon substrate in the vicinity of the opening of the trench can be improved.

An object of the present invention is to provide a technique for suppressing concentration of a gate electric field of a transistor, formed in an active region defied by an element isolation, in the vicinity of the element isolation.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 8 are cross-sectional views showing a method of forming trench isolation according to a preferred embodiment of the present invention;

FIG. 9 is a cross-sectional view showing a part of the structure of FIG. 8 in an enlarged manner;

FIG. 10 is a cross-sectional view showing a method of forming trench isolation according to the preferred embodiment of the present invention;

FIG. 11 is a cross-sectional view showing a part of the structure of FIG. 10 in an enlarged manner;

FIG. 12 is a cross-sectional view showing a method of forming trench isolation according to the preferred embodiment of the present invention;

FIGS. 13 to 20 are cross-sectional views showing a method of manufacturing a semiconductor device in the background art;

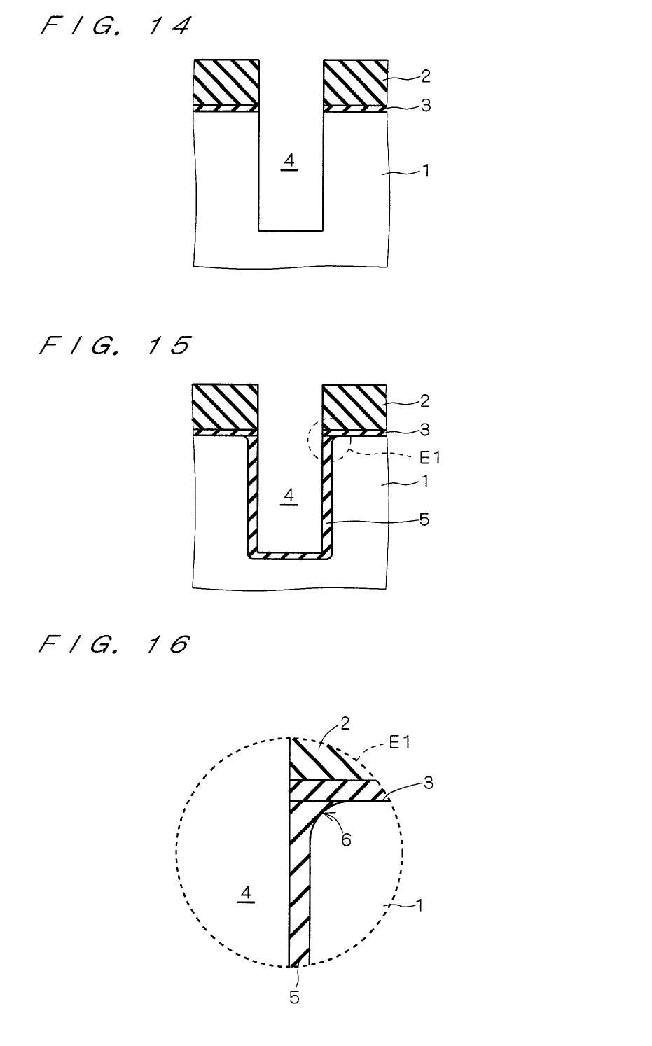

FIG. 21 is a graph showing problems of the semiconductor device in the background art;

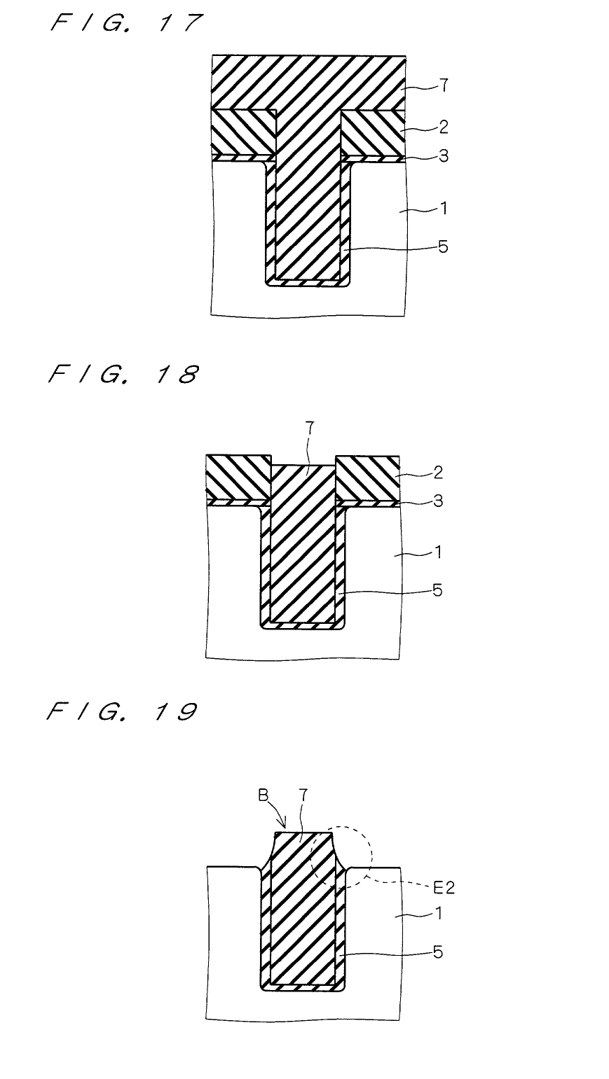

FIG. 22 is a cross-sectional view showing a part of the structure of FIG. 19 in an enlarged manner; and

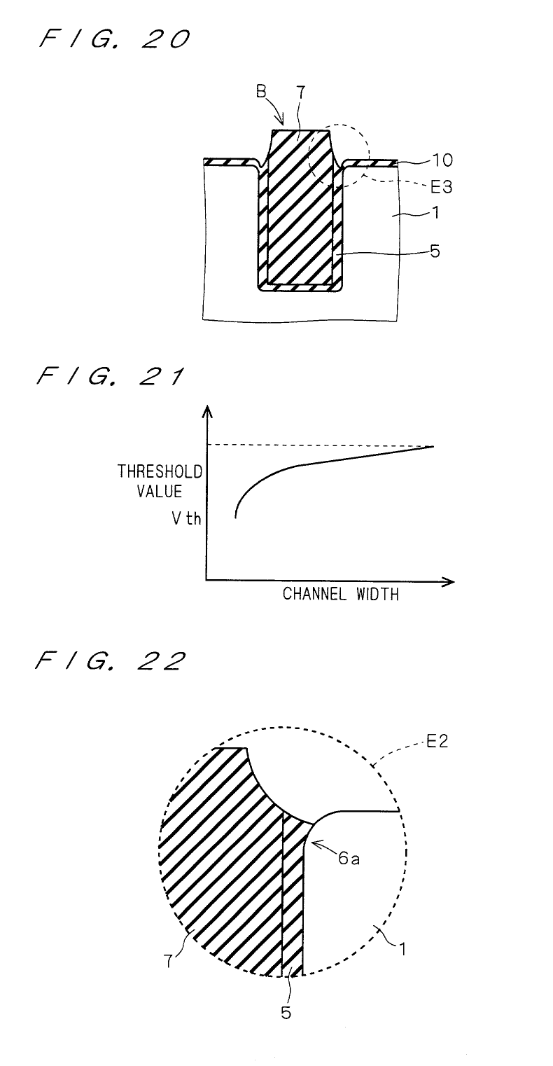

FIG. 23 is a cross-sectional view showing a part of the structure of FIG. 20 in an enlarged manner.

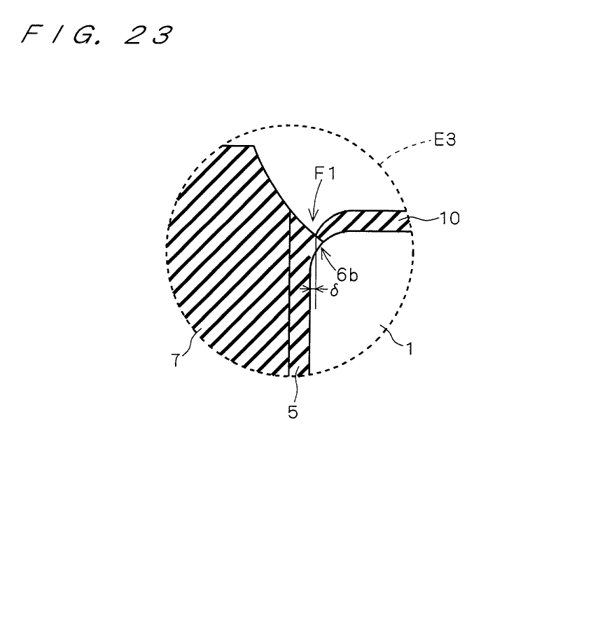

### DESCRIPTION OF THE PREFERRED EMBODIMENTS

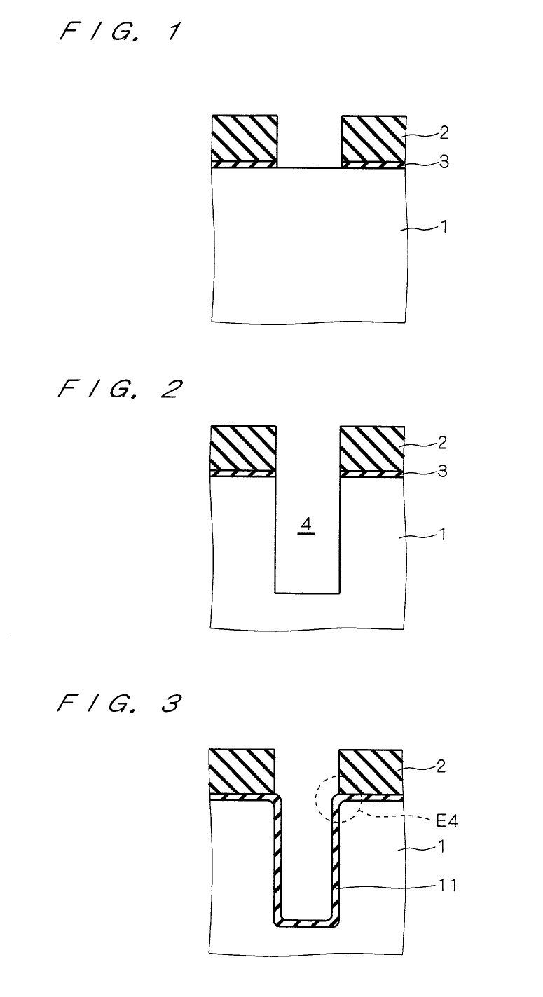

FIGS. 1 to 12 are cross-sectional views showing a method of manufacturing a semiconductor device according to a preferred embodiment of the present invention. A thermal oxide film 3 and a silicon nitride film 2 are formed in this order on a silicon substrate 1. The thicknesses of the thermal oxide film 3 and the silicon nitride film 2 are required to be thick enough not to be eliminated until a planarization step which will be described later. For example, the total of the thicknesses of the thermal oxide film 3 and the silicon nitride film 2 is set to be 100 nm or more.

The thermal oxide film 3 and the silicon nitride film 2 are patterned by the techniques such as photolithography or dry etching, to remain on an active region (FIG. 1), a region in which a MOSFET (not shown) is formed, for example. The size of an opening of the thermal oxide film 3 and the silicon nitride film 2 is determined depending on a circuit formed in the active region. In some case, the opening may range from 0.1 μm to hundreds of μm in a same silicon wafer.

Next, the silicon substrate 1 is etched using the thermal oxide film 3 and the silicon nitride film 2 as a mask to form a trench 4 (FIG. 2). That is, the trench 4 is formed in the silicon substrate 1 in a position which allows exposure of the thermal oxide film 3. Consequently, the thermal oxide film 3 exists in the periphery of an opening of the trench 4. The depth of the trench 4 is determined depending on the width of the opening of the trench 4. In an integrated circuit of high integration having an opening width of 0.14 μm or less, the depth of a trench is set to be 0.3 μm or less.

Thereafter, RTO (rapid thermal oxidation) is performed to oxidize a surface of the thermal oxide film 3 exposed from the silicon nitride film 2 to the trench and an inner wall of the trench 4. An oxide film obtained therefrom forms an oxide film 11 together with the oxide film 3 (FIG. 3). FIG. 4 is a cross-sectional view showing E4 in an enlarged manner which is a part of the structure of FIG. 3. A rounded portion 12 is formed in the vicinity of the opening of the trench 4 at a boundary between the oxide film 11 and the silicon substrate 1. A thickness t of the oxide film 11 at the trench 4 is set to be 50 nm or less, ensuring width of the trench 4 so that filling of the trench 4 with an oxide in a following step is allowed.

It is desirable to perform such RTO at a high temperature of 1000° C. or more, since the rounded portion 12 may not have an appropriate curvature by the oxidation at a temperature of not more than 1000° C. It is therefore desirable to set a rate of temperature rising to be high so that the thickness of the oxide film oxidized at a temperature of not more than 1000° C. is reduced. For example, the rate of temperature rising is preferably set to be 100° C. per second or more. As an oxidation atmosphere, it is favorable that a percentage of a moisture content to a total gas content used for oxidation is from 20 to 40%. When RTO is performed in an atmosphere having the percentage of the moisture content over 40%, a degree of effectiveness of rounding the rounded portion 12 is high. In this case, it is difficult to define the thickness of the oxide film 11 to be thin, for example a thickness of 50 nm or less, due to a high degree of oxidation rate. In contrast, when RTO is performed in an atmosphere having the percentage of the moisture content which is from 0% to less than 20%, the degree of effectiveness of rounding the rounded portion 12 is small.

The trench 4 is filled with an oxide film 7 consisting of TEOS or formed by HDP-CVD method (FIG. 5). As mentioned above, the thickness t of the oxide film 11 is set within a range that allows filling of the trench 4. The oxide film 7 is planarized using the silicon nitride film 2 as a stopper by the known planarization methods such as etching or chemical-mechanical polishing (FIG. 6). As mentioned above, the thicknesses of the thermal oxide film 3 and the silicon nitride film 2 are set so that the silicon nitride film 2 remains as a stopper during planarization.

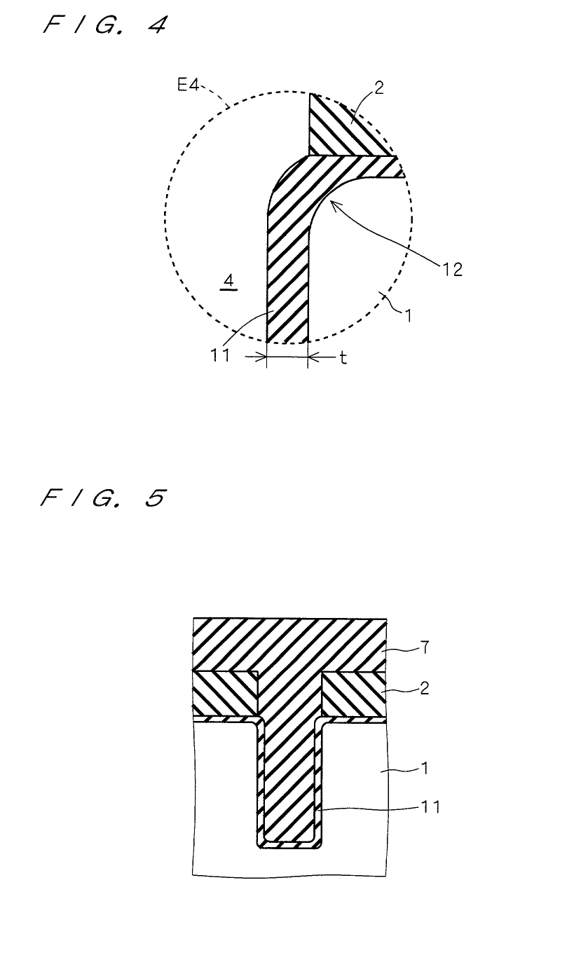

Next, the silicon nitride film 2 is removed (FIG. 7). Thereafter, a surface of the silicon substrate 1 is exposed once by etching a silicon oxide film. Furthermore, an oxide film involved during ion implantation into an active region (not shown) is formed once on the surface of the silicon substrate 1, which is removed after ion implantation. The oxide film 7 is also removed partially at the periphery during removal of this oxide film, to obtain trench type element isolation A (FIG. 8). FIG. 9 is a cross-sectional view showing E5 in an enlarged manner which is a part of the structure of FIG. 8. The size of a rounded portion 12a formed at a boundary between the oxide film 11 and the silicon substrate 1 is smaller than the size of the rounded portion 12.

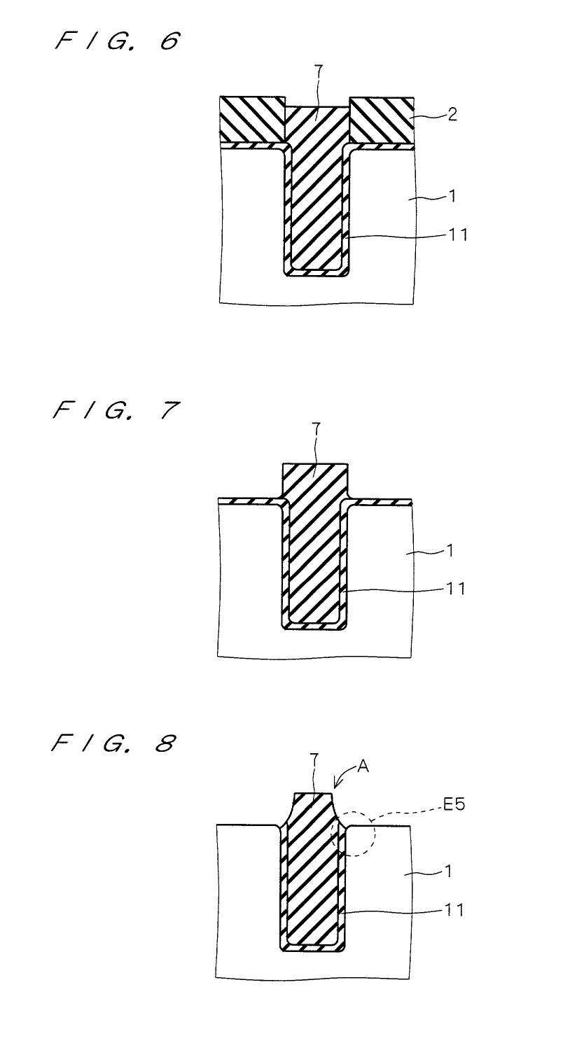

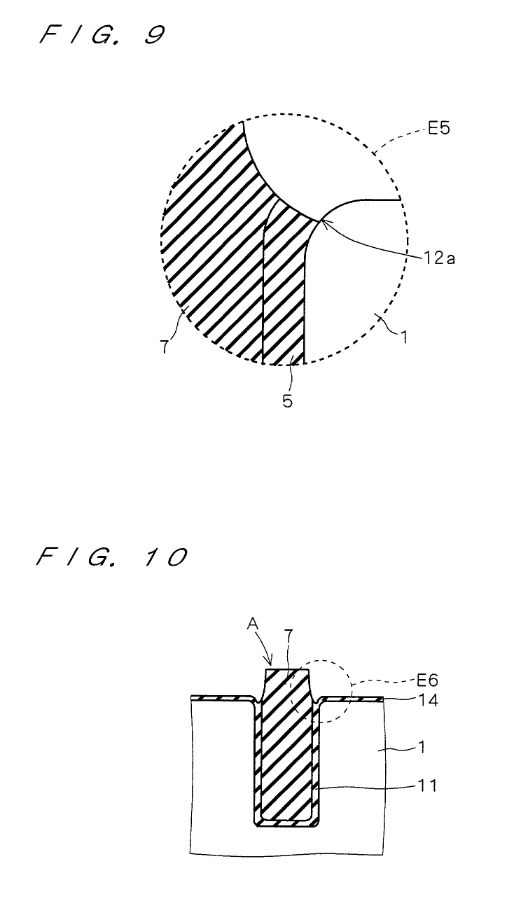

Next, RTO is performed under the same condition as mentioned above to form a gate oxide film 14 (FIG. 10). FIG. 11 is a cross-sectional view showing E6 in an enlarged manner which is a part of the structure of FIG. 10. A rounded portion 12b is formed at a boundary between the oxide film 11, the gate oxide film 14 and the silicon substrate 1. The shape of the rounded portion 12, formed once in the silicon substrate 1, is a rounded convex in the vicinity of the opening of the trench 4 and further rounded by forming the gate oxide film 14.

A recess F2 having a convex shape toward the silicon substrate 1, namely giving a concave shape to the oxide film 11 and the gate oxide film 14 as an integral insulating film, is formed at a boundary between the oxide film 11 and the gate oxide film 14. A radius of curvature of the rounded portion 12b and a radius of curvature of the gate oxide film 14 can be made larger than a radius of curvature of the rounded portion 6b by performing RTO under the condition as mentioned above. Therefore, a gate electric field is concentrated less in the rounded portion 12b than in the rounded portion 6b and the recess F2 is less noticeable than the recess F1 in the background art. In addition, a bottom of the recess F2 is likely to be arranged in a position more approximated to an inside of the trench 4 than a boundary between the silicon substrate 1 and the oxide film 11, namely in a position more approximated to the oxide film 7 by a distance d (>0). For example, the radius of curvature of the rounded portion 12b is set to be 30 nm or more.

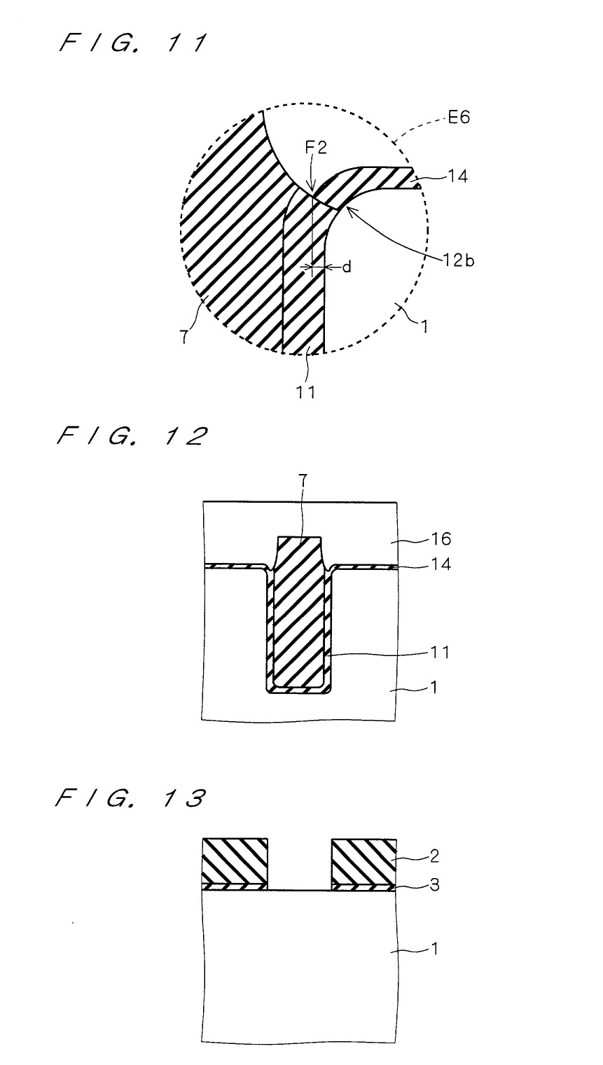

FIG. 12 shows a structure in which a gate electrode 16 is formed on the trench element isolation A and the gate oxide film 14 shown in FIG. 10. It is possible to enlarge the radius of curvature of the rounded portion 12b shown in FIG. 11, to suppress a degree of the recess F2 and to arrange the bottom of the recess F2 inside the trench 4. Consequently, a degree of concentration of a gate electric field, based on a gate potential applied to the gate electrode 16, is lower than the background structure. As a result, decrease in a threshold value caused by the factors such as a reverse narrow channel effect can be suppressed.

Further, stress imposed on the silicon substrate 1 during oxidation can be reduced by forming the gate oxide film 14 at a temperature of 1000° C. or more. Due to this, junction leakage current can be reduced as well.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a first insulating film formed on an inner wall of a trench formed in a silicon substrate; and
a second insulating film formed on a surface of said silicon substrate,
wherein a bottom of a concave portion defined by said first insulating film and said second insulating film is arranged in a position more approximated to an inside of said trench than said inner wall of said trench.

2. The semiconductor device according to claim 1, wherein said silicon substrate has a convex shape with a radius of curvature of 30 nm or more in a vicinity of an opening of said trench.

3. The semiconductor device according to claim 1, wherein said first insulating film has a thickness of 50 nm or less.

4. The semiconductor device according to claim 2, wherein said first insulating film has a thickness of 50 nm or less.

5. A method of manufacturing a semiconductor device, comprising the steps of:
(a) obtaining a trench in a silicon substrate and a first silicon oxide film provided on said silicon substrate on a periphery of an opening of said trench;
(b) oxidizing said first silicon oxide film exposed to said trench and an inner wall of said trench by performing a first RTO to form a second silicon oxide film;
(c) filling an inside of said trench with a third silicon oxide film;
(d) exposing a surface of said silicon substrate with etching for silicon oxide; and
(e) performing a second RTO to form a fourth silicon oxide film on said surface of said silicon substrate.

6. The method of manufacturing a semiconductor device according to claim 5, wherein said first RTO and said second RTO are performed at a temperature of 1000° C. or more.

7. The method of manufacturing a semiconductor device according to claim 6, wherein a rate of temperature rising in said first RTO and said second RTO is 100° C. per second or more.

8. The method of manufacturing a semiconductor device according to claim 5, wherein a percentage of a moisture content to a total gas content in said first RTO and said second RTO is from 20 to 40%.

9. The method of manufacturing a semiconductor device according to claim 6, wherein a percentage of a moisture content to a total gas content in said first RTO and said second RTO is from 20 to 40%.

10. The method of manufacturing a semiconductor device according to claim 7, wherein a percentage of a moisture content to a total gas content in said first RTO and said second RTO is from 20 to 40%.
